(19) United States
(12) Patent Application Publication
(10) Pub. No.: US 2011/0139240 A1
(43) Pub. Date: Jun. 16, 2011

(54) PHOTOVOLTAIC WINDOW LAYER

(75) Inventors: Arnold Allenic, Ann Arbor, MI (US); Benyamin Buller, Sylvania, OH (US); Markus Gloeckler, Perrysburg, OH (US); Imran Khan, Perrysburg, OH (US); Viral Parikh, Toledo, OH (US); Rick C. Powell, Ann Arbor, MI (US); Igor Sankin, Perrysburg, OH (US); Gang Xiong, Perrysburg, OH (US)

(73) Assignee: First Solar, Inc., Perrysburg, OH (US)

(21) Appl. No.: 12/969,075

(22) Filed: Dec. 15, 2010

Related U.S. Application Data
(60) Provisional application No. 61/286,630, filed on Dec. 15, 2009.

(51) Int. Cl. H01L 31/0216; H01L 31/0224

(52) U.S. Cl. 136/256; 438/98; 257/E31.126

(57) ABSTRACT

A discontinuous or reduced thickness window layer can improve the efficiency of CdTe-based or other kinds of solar cells.

### CLAIM OF PRIORITY

This application claims priority to U.S. Provisional Patent Application No. 61/286,630, filed on Dec. 15, 2009, which is incorporated herein by reference in its entirety.

### TECHNICAL FIELD

This invention relates to a solar cell with a discontinuous or reduced thickness window layer.

### BACKGROUND

Photovoltaic devices can include transparent thin films that are also conductors of electrical charge. For example, a photovoltaic device can include a semiconductor window layer and a semiconductor absorber layer to convert solar power into electrical power. Photovoltaic devices can be inefficient at converting solar power to electrical power.

### DESCRIPTION OF DRAWINGS

FIG. 1 is a schematic of a photovoltaic device having multiple semiconductor layers and a metal back contact.

FIG. 2 is a schematic of a photovoltaic device having one or more than one junction between the absorber layer and transparent conductive oxide layer.

FIG. 3 is a scanning electron microscope (SEM) image showing the increased discontinuity and reduction in the thickness of the cadmium sulfide window layer.

FIG. 4 is a scanning electron microscope (SEM) image showing the increased discontinuity and apparent reduction in the thickness of the cadmium sulfide window layer caused by absorber doping.

### DETAILED DESCRIPTION

A solar cell device can include various layers, including, for example, barrier layer, a layer of transparent conductive oxide (TCO)/buffer, a semiconductor window layer, a semiconductor absorber layer, and a back contact, all deposited adjacent to a substrate. Each layer can include one or more deposits of suitable material. For example, a photovoltaic device can include a semiconductor layer including two layers of semiconductor, a semiconductor window layer and a semiconductor absorber layer. A photovoltaic device layer can cover a portion or all of the area on which it is deposited. General experience suggests that the semiconductor window layer can be continuous for good solar cell performance. For example, in the current technology device design, the semiconductor window layer is typically thicker than 750 angstroms and highly continuous providing 80-90% coverage of the underlying TCO.

A high performing solar cell device can include a semiconductor window layer that can be thin, or non-conformal, or discontinuous, and can provide only 30 to 70% coverage of the underlying TCO layer. The reduction of the semiconductor window layer's thickness can improve the quantum efficiency in the blue spectrum of light and hence increase the short circuit current density of the solar cell or photovoltaic module. This device design can also achieve a reduction in the cost of production since less semiconductor window layer material is utilized and the overall improvement in the quantum efficiency and conversion efficiency of the solar cell. This design can also include a method of improving the conversion efficiency of a thin film photovoltaic device by inducing openings in the window layer while avoiding issues of TCO/absorber shunting.

Absorption of light by the window layer can be one of the phenomena limiting the conversion efficiency of a photovoltaic device. Generally, it is desirable to keep the window layer as thin as possible to allow a higher fraction of photons with energy above its band gap to reach the absorber. However, for most thin-film photovoltaic devices, if the window layer is too thin, a loss in performance can be observed due to lower open circuit voltage (V_{oc})/fill factor (FF).

A photovoltaic device can include a substrate, a transparent conductive oxide layer adjacent to the substrate, a discontinuous semiconductor window layer adjacent to the transparent conductive oxide layer, a semiconductor absorber layer adjacent to the semiconductor window layer, and a junction formed between the semiconductor absorber layer and the transparent conductive oxide layer. The discontinuous semiconductor window layer can provide 20 to 80% or 30 to 70% coverage of the adjacent transparent conductive oxide layer. The semiconductor absorber layer can absorb 5% to 45% more photons with a wavelength of less than 520 nm than the same absorber layer without any junctions to the transparent conductive oxide layer. The semiconductor absorber layer can absorb at least 10% more blue light than the same absorber layer without a junction to the transparent conductive oxide layer. The equivalent uniform thickness of the semiconductor window layer can be any suitable thickness. The equivalent uniform thickness of the semiconductor window layer can be less than 2500 angstroms, for example in the range 200 angstroms to 2500 angstroms. The equivalent uniform thickness of the semiconductor window layer can be less than 1200 angstroms. The equivalent uniform thickness of the semiconductor window layer can be in the range of 150 angstroms to 1200 angstroms, or 400 angstroms to 1200 angstroms or any other suitable thickness. The equivalent uniform thickness of the semiconductor window layer can be less than 750 angstroms. The equivalent uniform thickness of the semiconductor window layer can be in the range of 150 angstroms to 500 angstroms or 250 angstroms to 400 angstroms.

The substrate can include glass. The semiconductor window layer can include cadmium sulfide, zinc sulfide, or an alloy of cadmium sulfide and zinc sulfide, or any other suitable material. The semiconductor absorber layer can include cadmium telluride or cadmium zinc telluride, or any other suitable material. The transparent conductive oxide layer can include zinc oxide, tin oxide, or cadmium stannate, or any other suitable material.

A photovoltaic device can include a substrate, a transparent conductive oxide layer adjacent to the substrate, a discontinuous semiconductor window layer adjacent to the transparent conductive oxide layer, and a semiconductor absorber layer including a dopant. The dopant can be capable of interacting with and fluxing the adjacent semiconductor window layer. The dopant can include silicon, germanium, chlorine, or sodium, or any other suitable material. The semiconductor absorber layer can include a dopant concentration in the range of 10¹⁵ to 10¹⁸ atoms/cm³ or 10¹⁶ to 10¹⁷ atoms/cm³, or any other suitable range or value. The semiconductor absorber layer can be annealed. The dopant can accumulate at an absorber layer/window layer interface. The photovoltaic device can include one or more junctions between the semiconductor absorber layer and the transparent conductive oxide layer. The semiconductor window layer can provide 20 to 80% coverage of the adjacent transparent conductive oxide layer. The dopant can electrically passivate the transparent conducting oxide layer /absorber layer junction to maintain open circuit voltage (V_{oc}) and fill factor (FF). Improvements in carrier collection efficiency and/or reduction in open circuit resistance are responsible for improved FF.

The semiconductor absorber layer can absorb 5% to 45% more photons with a wavelength of less than 520 nm than the same absorber layer without a junction to the transparent conductive oxide layer. The semiconductor absorber layer can absorb at least 10% more blue light than the same absorber layer without a junction to the transparent conductive oxide layer. The thickness of the semiconductor absorber layer can be in the range of 0.5 micron to 7 microns. The equivalent uniform thickness of the semiconductor window layer can be less than 1200 angstroms.

The semiconductor window layer can include cadmium sulfide, zinc sulfide, or an alloy of cadmium sulfide and zinc sulfide, or any other suitable material. The semiconductor absorber layer can include cadmium telluride, or cadmium zinc telluride, or any other suitable material. The transparent conductive oxide can include zinc oxide, tin oxide, or cadmium stannate, or any other suitable material.

A method of manufacturing a photovoltaic device can include depositing a transparent conductive oxide layer adjacent to a substrate, forming a discontinuous semiconductor window layer adjacent to the transparent conductive oxide layer, and depositing a semiconductor absorber layer adjacent to the window layer, and forming one or more than one junction between the absorber layer and transparent conductive oxide layer. The step of forming a junction can include forming a plurality of junctions between the absorber layer and transparent conductive oxide layer.

A method of manufacturing a photovoltaic device can include depositing a transparent conductive oxide layer adjacent to a substrate, forming a semiconductor window layer adjacent to the transparent conductive oxide layer. The semiconductor window layer can include and/or provide spotty coverage of the adjacent transparent conductive oxide layer. This can result in increased efficiency. The method can include depositing a semiconductor absorber layer adjacent to the semiconductor window layer. The semiconductor window layer can provide 20 to 80% coverage of the adjacent transparent conductive oxide layer. The window layer's irregular or spotty coverage of the adjacent transparent conductive oxide layer can be formed by doping the semiconductor absorber layer with a dopant and diffusing the dopant to an interface between the window layer and the absorber layer flux the window layer away. The window layer can be partially fluxed away. The spotty coverage of the adjacent transparent conductive oxide layer can result in junctions between the transparent conducting oxide layer and the absorber layer which can allow more photons with energy above the window layer material's band gap to be absorbed.

The diffusion of the dopant can electrically passivate the junction between the transparent conducting oxide layer and the absorber layer to maintain open circuit voltage (V_{oc}) and/or fill factor (FF), respectively. Improvements in carrier collection efficiency and/or reduction in open circuit resistance are responsible for improved fill factor. The window layer's spotty coverage of the adjacent transparent conductive oxide layer can increase the absorption of the blue spectrum of light in the absorber and hence increase the short circuit current of the photovoltaic device.

The dopant can include silicon, germanium, chlorine, or sodium, or any other suitable material. The step of doping the semiconductor absorber layer can include doping the semiconductor absorber layer to a dopant concentration in the range of 10¹⁵ to 10¹⁸ atoms/cm³ or 10¹⁶ to 10¹⁷ atoms/cm³, or any other suitable range or value. The semiconductor absorber layer can be doped by injecting a powder in a vapor transport deposition process, wherein the powder can include a blend of cadmium telluride powder and silicon powder with a dopant/absorber ratio anywhere up to 10,000 ppma. The semiconductor absorber layer can be doped after forming the semiconductor absorber layer. The thickness of the semiconductor absorber layer can be in the range of 0.5 micron to 7 microns. The method can further include an annealing step to promote the dopant diffusion. The anneal temperatures can be in the range of about 300 to about 500 degree C., for example about 400 to about 450 degree C., or any other suitable temperature or range. The step of annealing can include annealing the substrate in an environment including cadmium chloride. Alternatively, the semiconductor absorber layer can be doped by a suitable material after forming the semiconductor absorber layer. For example, the semiconductor absorber layer can be doped during annealing of the semiconductor absorber layer. The doping can occur at any suitable anneal temperature, for example in the range of about 300 to about 500 degree C.

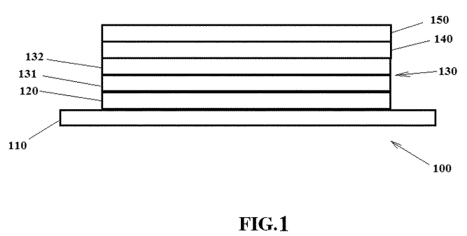

Referring to FIG. 1, photovoltaic device 100 can include a transparent conductive oxide layer 120 deposited adjacent to a substrate 110. Transparent conductive oxide layer 120 can be deposited on substrate 110 by sputtering, chemical vapor deposition, or any other suitable deposition method. Substrate 110 can include a glass, such as soda-lime glass. Transparent conductive oxide layer 120 can include any suitable transparent conductive oxide material, including tin oxide, zinc oxide, or cadmium stannate. A semiconductor layer 130 can be formed or deposited adjacent to transparent conductive oxide layer 120 which can be annealed. Semiconductor layer 130 can include window layer 131 and absorber layer 132.

Window layer 131 can include a semiconductor material and absorber layer 132 can include a semiconductor material. Window layer 131 of semiconductor layer 130 can be deposited adjacent to transparent conductive oxide layer 120. Window layer 131 can include any suitable window material, such as cadmium sulfide, zinc sulfide, an alloy of cadmium sulfide and zinc sulfide, or any other suitable material. Window layer 131 can be deposited by any suitable deposition method, such as sputtering or vapor transport deposition. Absorber layer 132 can be deposited adjacent to window layer 131. Absorber layer 132 can be deposited on window layer 131. Absorber layer 132 can be any suitable absorber material, such as cadmium telluride, or cadmium zinc telluride, or any other suitable material. Absorber layer 132 can be deposited by any suitable method, such as sputtering or vapor transport deposition. TCO layer can include any suitable TCO material, including zinc oxide, tin oxide, cadmium stannate, or any other suitable material.

Window layer 131 can be thin, and/or non-conformal, and/or discontinuous, and can provide only 20 to 80% or 30 to 70% coverage of the underlying TCO layer, or any other suitable percentage of coverage of the TCO layer. The reduction of the window layer's thickness can improve the device quantum efficiency in the blue spectrum of light and hence increase its short circuit current. In some embodiments, the conversion efficiency of photovoltaic device 100 can be improved by doping the absorber layer with the intention to modify the morphology of the window layer. The increase in conversion efficiency can be driven by the simultaneous increases in short circuit current (I_{sc}), fill factor (FF) and/or open circuit voltage (V_{oc}). Change in the microstructure of window layer 131 from continuous to irregular or spotty can be made by doping absorber layer 132 with a dopant and diffusing the dopant to the absorber layer/window layer interface to partially flux the window layer away. The consumption of window layer 131 can result in junctions between the transparent conducting oxide layer 120 and absorber layer 132 allowing more photons with energy above the semiconductor window layer material's band gap to be absorbed. Diffusion of the dopant to the p-n heterointerface is necessary to electrically passivate the TCO/absorber junction to maintain V_{oc}. Improvements in carrier collection efficiency and/or reduction in open circuit resistance result in higher fill factor. The dopant can include any suitable material. For example, the dopant can include silicon, germanium, chlorine, or sodium.

Back contact 140 can be deposited adjacent to absorber layer 132. Back contact 140 can be deposited adjacent to semiconductor layer 130. A back support 150 can be positioned adjacent to back contact 140. A photovoltaic device can have a cadmium sulfide (CdS) layer as a semiconductor window layer and a cadmium telluride (CdTe) layer as a semiconductor absorber layer. Window layer 131 can also include zinc sulfide (ZnS) or a ZnS/CdS alloy. Absorber layer 132 can include a cadmium-zinc-telluride (Cd—Zn—Te) alloy, a copper-indium-gallium-selenium (Cu—In—Ga—Se) alloy, or any other suitable material. The dopant can also be any suitable element known to interact and flux the window material.

In some embodiments, photovoltaic device 100 can also include a barrier layer between substrate 110 and transparent conductive oxide layer 120. The barrier layer can include silicon oxide or any other suitable material. In some embodiments, photovoltaic device 100 can also include a buffer layer between transparent conductive oxide layer 120 and window layer 131. The buffer layer can include tin oxide, zinc oxide, zinc tin oxide, cadmium zinc oxide, or any other suitable material.

In some embodiments, the disclosed invention can include a process depositing a thin film solar cell stack on a substrate configuration and where the absorber layer can be doped with a dopant such as Si, an annealing process that can drive the impurity toward the absorber/window interface, a reaction between the window and the dopant resulting in partial fluxing of the window layer material by the dopant, and a passivation mechanism for the TCO/absorber contacts.

If every incident photon on a solar cell generated an electron-hole pair, each of the photo carriers would make it to the depletion region where they could be separated and collected. Photons with energy less than the bandgap have insufficient energy to generate photo-carriers. Even if it has the sufficient energy, it need not contribute to the photocurrent. Quantum efficiency of a photon of certain wavelength is the probability that the photon contributes an electron to the photocurrent. It is the measure of the effectiveness of a device to produce electronic charge from incident photons. Quantum efficiency is expected to be zero for photons with energy less than the absorber bandgap. For photons with a larger energy, quantum efficiency can be as large as 100% but is often lower. One reason can be many photons that enter the top of the cell get adsorbed in the upper layers, never reaching the absorber layer below. This is true for heterojunctions and photons with energy larger than the bandgap of the TCO and window layer.

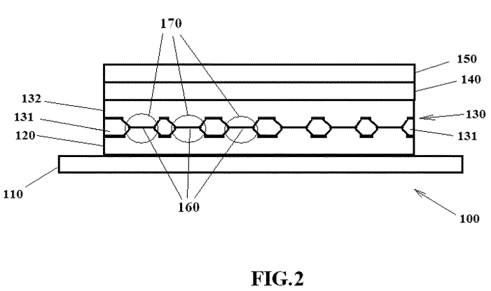

Referring to FIG. 2, in some embodiments, semiconductor window layer 131 can be discontinuous or spotty. Junctions 170 can be formed between TCO layer 120 and absorber layer 132 on TCO/absorber interface 160, allowing more photons with energy above the semiconductor window layer material's band gap to be absorbed. Therefore, junction 170 between absorber layer 132 and transparent conductive oxide layer 120 can improve the quantum efficiency in the blue spectrum of light and hence increase the short circuit current of the photovoltaic device. Absorber layer 132 can contain a suitable amount of dopant to increase the efficiency of the photovoltaic cell. Window layer 131 being discontinuous can cause one or more junctions between absorber layer 132 and TCO layer 120. Absorber layer 132 can absorb 5% to 45%, 10% to 25%, or any suitable percentage more photons having a wavelength less than 520 nm than the same absorber layer would without the presence of a junction 170 between the absorber layer and TCO layer 120. Absorber layer 132 can absorb at least 10% more blue light than it would without a junction 170.

Absorber layer 132 to include an amount of a dopant sufficient to increase the efficiency of the photovoltaic cell in absorbing photons, which can lead to a higher electrical power output. Any suitable dopant can be included in absorber layer 132, including silicon, germanium, chlorine, or sodium, or any other suitable dopant. The dopant material can be included in absorber layer 132 in any suitable amount. For example, the dopant material can be present in a concentration of in the range of 10¹⁵ to 10¹⁸ atoms/cm³ or 10¹⁶ to 10¹⁷ atoms/cm³, or any other suitable range or value.

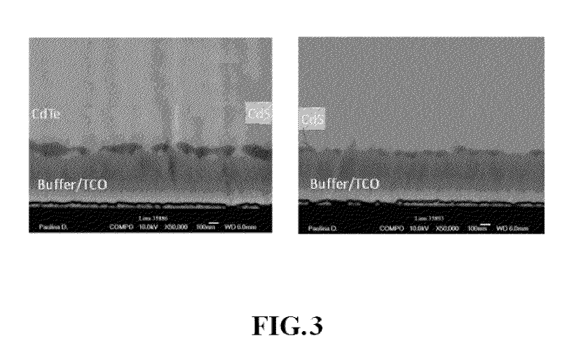

Referring to FIG. 3, the scanning electron microscope (SEM) image shows the increased discontinuity and reduction in the thickness of the cadmium sulfide window layer. The reduction of the CdS thickness can improve the quantum efficiency in the blue spectrum of light and hence increase the Jsc (short circuit current density) of the solar cell. This new device design achieves a reduction in the cost of production since less cadmium sulfide or other window layer material can be utilized and the overall improvement in the quantum efficiency and conversion efficiency of the solar cell.

The photovoltaic device with reduced thickness window layer can have about 6 percent efficiency increase and 8 percent short circuit current (I_{sc}) increase respectively compared to the control group. The equivalent uniform thickness of the semiconductor window layer can be less than 2500 angstroms, for example in the range of 200 angstroms to 2500 angstroms. The equivalent uniform thickness of the semiconductor window layer can be less than 1200 angstroms, for example in the range of 150 angstroms to 1200 angstroms, or 400 angstroms to 1200 angstroms. The equivalent uniform thickness of the semiconductor window layer can be less than 750 angstroms, for example in the range of 150 angstroms to 500 angstroms, 200 angstroms to 400 angstroms, or 300 angstroms to 350 angstroms, or any other suitable thickness.

In some embodiments, the conversion efficiency of a thin film photovoltaic device can be improved by doping the absorber layer with the intention to modify the morphology of the window layer. Change in the microstructure of the semiconductor window layer from continuous to irregular or spotty can be done by doping the absorber layer with a dopant and diffusing the dopant to the absorber/window layer interface to partially flux the window layer away. The consumption of the semiconductor window layer can result in junctions between the TCO and absorber allowing more photons with energy above the semiconductor window layer material's band gap to be absorbed. Diffusion of the dopant to the p-n heterointerface is necessary to electrically passivate the TCO/absorber junction to maintain V_{oc}.

Improvements in carrier collection efficiency \and/or reduction in open circuit resistance result in higher fill factor. The dopant can include silicon. The dopant can include chlorine. The dopant can also be any suitable element known to interact and flux the window material. The step of doping the semiconductor absorber layer can include doping the semiconductor absorber layer to a dopant concentration in the range of 10¹⁵ to 10¹⁸ atoms/cm³ or 10¹⁶ to 10¹⁷ atoms/cm³, or any other suitable range or value. The absorber can be doped by injecting a powder in a vapor transport deposition or closed space sublimation system. The powder can include of a blend of CdTe powder and silicon powder. The dopant to absorber ratio can be up to 10,000 ppma, or 200 to 2,000 ppma, or any suitable ratio.

In some embodiments, a desired dopant depth profile in the absorber layer can have the dopant piling up deep into the absorber layer. The thickness of the absorber layer can be in the range of 0.5 micron to 7 microns. The thickness of the absorber layer can be about 2.6 microns. The dopant concentration can be in the range of 5×10¹⁶ to 5×10¹⁸ cm⁻³ in the bulk of the absorber further from the window layer. The dopant concentration can be in the range of 10¹⁷ to 10¹⁹ cm⁻³ in the bulk of the absorber layer closer to the window layer. A following annealing process can promote the diffusion and accumulation of the dopant near the CdS layer. The anneal temperatures can be any suitable temperature or range. For example, the anneal temperature can be in the range of 300 to 500 degree C. The anneal temperature can be in the range of 400 to 450 degree C. The anneal can be carried out in a suitable environment. For example, the anneal can be carried out in a cadmium chloride (CdCl₂) environment.

The effect of absorber doping on the quantum efficiency (QE) can be clear. Improvements in blue (400-500 nm) and red (600-750 nm) absorption are visible in the cell having a doped absorber. The deposited CdS window layer thickness is the same in both the photovoltaic device with doped absorber layer and the control group. The most sizeable improvement can be in blue absorption (up to 30%) while the red absorption can increase by at most 5%. Both of these numbers depend on the silicon concentration in CdTe absorber. The device short circuit current (I_{sc}) and efficiency can increase resulting from structural modifications brought to the CdS window layer as an effect of Si doping of CdTe absorber layer.

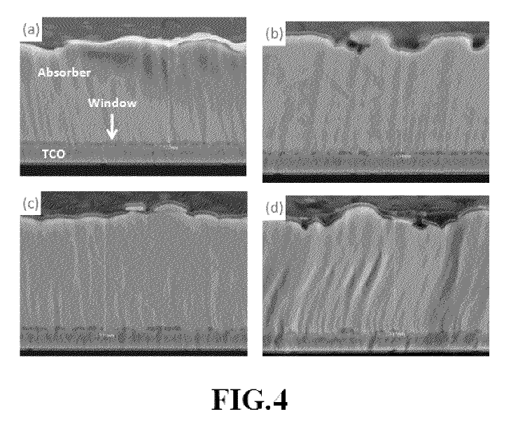

Referring to FIG. 4, the scanning electron microscope (SEM) image shows the increased discontinuity and reduction in the thickness of the CdS window layer. It can be seen that the microstructure of the CdS window layer can change from continuous to irregular or spotty, with TCO/absorber junctions forming as more silicon dopant is incorporated in the absorber. From the experiments, the sample with the highest number of TCO/absorber junction has the highest sensitivity to blue light and the highest Si uptake. The deposited CdS window layer thickness is the same in both the photovoltaic device with doped absorber layer and the control group. The devices with high short circuit current (I_{sc}) can also maintain a reasonable open circuit voltage (V_{oc}) despite the higher fraction of TCO/absorber junctions. The role of the silicon dopant is not only to partially open up areas in the window layer, but also to passivate the heterointerface. The fill factor (FF) of high short circuit current (I_{sc}) devices can be high, because of improved carrier collection efficiency and/or reduction in open circuit resistance, resulting in higher fill factor.

A number of embodiments of the invention have been described. Nevertheless, it will be understood that various modifications may be made without departing from the spirit and scope of the invention. It should also be understood that the appended drawings are not necessarily to scale, presenting a somewhat simplified representation of various preferred features illustrative of the basic principles of the invention.

What is claimed is:

1. A photovoltaic device comprising:
a substrate;
a transparent conductive oxide layer adjacent to the substrate;
a discontinuous semiconductor window layer adjacent to the transparent conductive oxide layer;
a semiconductor absorber layer adjacent to the semiconductor window layer; and
a junction formed between the semiconductor absorber layer and the transparent conductive oxide layer.

2. The photovoltaic device of claim 1, wherein the semiconductor window layer provides 20 to 80% coverage of the adjacent transparent conductive oxide layer.

3. The photovoltaic device of claim 2, wherein the semiconductor window layer provides 30 to 70% coverage of the adjacent transparent conductive oxide layer.

4. The photovoltaic device of claim 1, wherein the semiconductor absorber layer absorbs 5% to 45% more photons with wavelength of less than 520 nm than the same absorber layer configured without a junction to the transparent conductive oxide layer.

5. The photovoltaic device of claim 4, wherein the semiconductor absorber layer absorbs 10% to 25% more photons with wavelength of less than 520 nm than the same absorber layer configured without a junction to the transparent conductive oxide layer.

6. The photovoltaic device of claim 1, wherein the semiconductor absorber layer absorbs at least 10% more blue light than the same absorber layer configured without a junction to the transparent conductive oxide layer.

7. The photovoltaic device of claim 1, wherein the equivalent uniform thickness of the semiconductor window layer is less than 1200 angstroms.

8. The photovoltaic device of claim 1, wherein the equivalent uniform thickness of the semiconductor window layer is in the range of 200 angstroms to 2500 angstroms.

9. The photovoltaic device of claim 1, wherein the semiconductor window layer comprises one or more of cadmium sulfide, zinc sulfide, or an alloy of cadmium sulfide and zinc sulfide.

10. The photovoltaic device of claim 1, wherein the semiconductor absorber layer comprises one or more of cadmium telluride or cadmium zinc telluride.

11. The photovoltaic device of claim 1, wherein the transparent conductive oxide layer comprises one or more of zinc oxide, tin oxide, or cadmium stannate.

12. A photovoltaic device comprising:
a substrate;
a transparent conductive oxide layer adjacent to the substrate;
a discontinuous semiconductor window layer adjacent to the transparent conductive oxide layer; and
a semiconductor absorber layer comprising a dopant, wherein the dopant is capable of interacting with and fluxing the adjacent semiconductor window layer.

13. The photovoltaic device of claim 12, wherein the dopant comprises one or more of silicon, germanium, chlorine, or sodium.

14. The photovoltaic device of claim 12, wherein the semiconductor absorber layer comprises a dopant concentration in the range of 10¹⁵ to 10¹⁸ atoms/cm³.

15. The photovoltaic device of claim 12, wherein the dopant accumulates at an interface between the absorber layer and the window layer.

16. The photovoltaic device of claim 12, further comprising one or more junctions between the semiconductor absorber layer and the transparent conductive oxide layer.

17. The photovoltaic device of claim 12, wherein the semiconductor window layer provides 20 to 80% coverage of the adjacent transparent conductive oxide layer.

18. The photovoltaic device of claim 16, wherein the dopant can electrically passivate the junction between the transparent conducting oxide layer and the semiconductor absorber layer junction to maintain open circuit voltage (V_{oc}) and fill factor (FF).

19. The photovoltaic device of claim 16, wherein the semiconductor absorber layer absorbs 5% to 45% more photons with wavelength of less than 520 nm than the same absorber layer configured without a junction to the transparent conductive oxide layer.

20. The photovoltaic device of claim 12, wherein the thickness of the semiconductor absorber layer is in the range of 0.5 to 7 microns.

21. The photovoltaic device of claim 12, wherein the equivalent uniform thickness of the semiconductor window layer is less than 1200 angstroms.

22. The photovoltaic device of claim 12, wherein the equivalent uniform thickness of the semiconductor window layer is in the range of 200 angstroms to 2500 angstroms.

23. The photovoltaic device of claim 12, wherein the semiconductor window layer comprises one or more of cadmium sulfide, zinc sulfide, or an alloy of cadmium sulfide and zinc sulfide.

24. A method of manufacturing a photovoltaic device comprising:
depositing a transparent conductive oxide layer adjacent to a substrate;
forming a discontinuous semiconductor window layer adjacent to the transparent conductive oxide layer; and
depositing a semiconductor absorber layer adjacent to the window layer; and
forming a junction between the absorber layer and transparent conductive oxide layer.

25. The method of claim 24, wherein the step of forming a junction comprises forming a plurality of junctions between the absorber layer and transparent conductive oxide layer.

26. A method of manufacturing a photovoltaic device comprising:
depositing a transparent conductive oxide layer adjacent to a substrate;
forming a discontinuous semiconductor window layer adjacent to the transparent conductive oxide layer, wherein the semiconductor window layer comprises spotty coverage of the adjacent transparent conductive oxide layer; and
depositing a semiconductor absorber layer adjacent to the semiconductor window layer.

27. The method of claim 26, wherein the semiconductor window layer can provide 20 to 80% coverage of the adjacent transparent conductive oxide layer.

28. The method of claim 26, wherein the spotty coverage of the adjacent transparent conductive oxide layer is formed by doping the semiconductor absorber layer with a dopant and diffusing the dopant to an interface of the window layer with the absorber layer to partially flux the window layer away.

29. The method of claim 26, wherein the spotty coverage of the adjacent transparent conductive oxide layer results in junctions between the transparent conducting oxide layer and the absorber layer allowing more photons with energy above the window layer material's band gap to be absorbed, electrically passivates the junction between the transparent conducting oxide layer and the absorber layer junction to maintain open circuit voltage (V_{oc}) and fill factor (FF), or increases the absorption of the blue spectrum of light and hence increase the short circuit current of the photovoltaic device.

30. The method of claim 28, wherein the dopant comprises one or more of silicon, germanium, chlorine, or sodium.

31. The method of claim 28, wherein the step of doping the semiconductor absorber layer comprises doping the semiconductor absorber layer to a dopant concentration in the range of 10¹⁵ to 10¹⁸ atoms/cm³.

32. The method of claim 28, wherein the semiconductor absorber layer can be doped by injecting a powder in a vapor transport deposition process, wherein the powder comprises a blend of cadmium telluride powder and silicon powder with a dopant/absorber ratio up to 10,000 ppma.

33. The method of claim 28, wherein the step of doping the semiconductor absorber layer comprises doping the semiconductor absorber layer after forming the semiconductor absorber layer.

34. The method of claim 28, further comprising annealing to promote the dopant diffusion.

35. The method of claim 34, wherein the anneal temperatures can be in the range of about 400 to about 450 degree C.

36. The method of claim 34, wherein the step of annealing comprises annealing the substrate in an environment including cadmium chloride.
